(19) United States
(12) Patent Application Publication
(10) Pub. No.: US 2024/0213326 A1
(43) Pub. Date: Jun. 27, 2024

(54) TWO DIMENSIONAL SEMICONDUCTOR TRANSISTOR, TWO DIMENSIONAL SEMICONDUCTOR WITH THE SAME AND MANUFACTURING METHOD THEREOF

(71) Applicant: KOREA UNIVERSITY RESEARCH AND BUSINESS FOUNDATION, Seoul (KR)

(72) Inventors: Hyun-Yong YU, Seoul (KR); Kyu Hyun HAN, Seoul (KR)

(73) Assignee: KOREA UNIVERSITY RESEARCH AND BUSINESS FOUNDATION, Seoul (KR)

(21) Appl. No.: 18/371,160

(22) Filed: Sep. 21, 2023

(30) Foreign Application Priority Data
Sep. 27, 2022 (KR) 10-2022-0122493

(51) Int. Cl. H01L 29/10; H01L 29/24; H01L 29/66; H01L 29/786

(52) U.S. Cl. CPC H01L 29/1054; H01L 29/24; H01L 29/66969; H01L 29/78681

(57) ABSTRACT

A two dimensional (2D) semiconductor transistor includes a gate electrode, a gate insulating film provided on the gate electrode, a 2D semiconductor layer provided on the gate insulating film and provided in a hetero-junction structure having a staggered band gap, a source electrode and a drain electrode provided on the 2D semiconductor layer and disposed to be spaced apart from each other. The 2D semiconductor layer includes a first semiconductor layer and a second semiconductor layer having mutually different electrical characteristics and at least partially overlapped with each other, and one of the first semiconductor layer and the second semiconductor layer is lightly doped with dopants.

### CROSS-REFERENCE TO RELATED APPLICATIONS

This application claims priority under 35 U.S.C. § 119 to Korean Patent Application No. 10-2022-0122493 filed on Sep. 27, 2022, in the Korean Intellectual Property Office, the disclosure of which is incorporated by reference herein in its entirety.

### BACKGROUND

Embodiments of the present disclosure described herein relate to a two dimensional semiconductor transistor, a two dimensional semiconductor device including the same, and a method for manufacturing the same.

Recently, studies and research on various types of devices based on dichalcogen which is transition metal and serves as a two dimensional (2D) semiconductor materials in the spotlight as a new semiconductor material to replace silicon in the future, has actively performed.

The above-described 2D semiconductor materials show more excellent atomic sharpness at the junction interface, as compared to a device manufactured through a hetero-structure, such as Si, Ge, SiGe, GaAs (group 3-5), which are used to manufacture an existing device in a field such as a hetero-structure-based tunneling and anti-ambipolar transistor device. Accordingly, the above-described 2D semiconductor materials may significantly reduce the degradation of the device performance due to interface trap

Recently, studies and researches have been performed on numerous technologies for a hetero-structure-based tunneling device and an anti-ambipolar Transistor (AAT) device have been studied to implement multi-level logic circuits, such as a ternary inverter or a quaternary inverter, to process multiple data.

### SUMMARY

Embodiments of the present disclosure provide a 2D semiconductor transistor, capable of adjusting an NDT peak by lightly doping dopants into only one of a first semiconductor layer and a second semiconductor layer of a 2D semiconductor transistor, and a method for manufacturing the same.

Embodiments of the present disclosure provide a 2D semiconductor device including an AAT device including a 2D semiconductor transistor and an AAT including a 2D semiconductor transistor in which neither first semiconductor layer nor second semiconductor layer is doped, which is applicable to a quaternary inverter logic circuit.

According to an aspect of the present disclosure, a two dimensional (2D) semiconductor transistor may include a gate electrode, a gate insulating film provided on the gate electrode, a 2D semiconductor layer provided on the gate insulating film and provided in a hetero-junction structure having a staggered band gap, a source electrode and a drain electrode provided on the two dimensional (2D) semiconductor layer and disposed to be spaced apart from each other, the 2D semiconductor layer may include a first semiconductor layer and a second semiconductor layer having mutually different electrical characteristics and at least partially overlapped with each other, and one of the first semiconductor layer and the second semiconductor layer may be lightly doped with dopants.

According to an embodiment of the present disclosure, the one of the first semiconductor layer and the second semiconductor layer may be a 2D semiconductor layer in an n type, and another of the first semiconductor layer and the second semiconductor layer may be a 2D semiconductor layer in a p-type.

According to an embodiment of the present disclosure, a dopant doped into the 2D semiconductor layer in the p-type, of the first semiconductor layer and the second semiconductor layer is a p-type dopant.

According to an embodiment of the present disclosure, a dopant doped into the 2D semiconductor layer provided in the n-type, of the first semiconductor layer and the second semiconductor layer may be an n-type dopant.

According to an embodiment of the present disclosure, the first semiconductor layer and the second semiconductor layer may include dichalcogen which is transition metal.

According to an embodiment of the present disclosure, the first semiconductor layer and the second semiconductor layer may include at least one 2D semiconductor material of MoS₂, WS₂, ReS₂, ReSe₂, PtSe2, HfS₂, MoSe₂, HfSe₂, HfTe₅, HfTe₂, ZrS₂, ZrSe₂, ZrTe₂, ZrS₃, ZrS₅, ZrTe₃, WSe₂, MoSe₂, black phosphorus (BP), 2D tellurium, GeSe, GaSe, GeAs, black AsP, or a-MnS.

According to an embodiment of the present disclosure, the source electrode may be connected to the one of the first semiconductor layer and the second semiconductor layer, and the drain electrode may be connected to another of the first semiconductor layer and the second semiconductor layer.

According to an embodiment of the present disclosure, the gate insulating film may include at least one of SiN, SiO2, GeO₂, TiO₂, ZnO, ITO, AZO, MgO, Al₂O₃, ZrO₂, ZrSiO₄, HfSiO₄, Si₃N₄, SrO, Ta₂O₅, Y₂O₃, HfO₂, La₂O₃, BaO, LaLuO₂, or LaAlO₃.

According to another aspect of the present disclosure, a 2D semiconductor may include a first AAT device and a second AAT device having mutually different electrical characteristics and connected to each other in parallel, the first AAT device and the second AAT device may be 2D semiconductor transistors, respectively, each 2D semiconductor transistor having a 2D semiconductor layer provided in a hetero-junction structure having a staggered band gap, the 2D semiconductor layer may include a first semiconductor layer and a second semiconductor layer which have mutually different electrical characteristics and are at least partially overlapped with each other, one of the first semiconductor layer and the second semiconductor layer in one of the first AAT device and the second AAT device may be lightly doped with a dopant, and another of the first AAT device and the second AAT device may include a first semiconductor layer and a second semiconductor layer which are not doped with dopants.

According to an embodiment of the present disclosure, a negative-differential-transconductance (NDT) peak of the first AAT device and an NDT peak of the second AAT device may be different from each other.

According to an embodiment of the present disclosure, the first semiconductor layer of the first AAT device and the second AAT device may be a 2D semiconductor in an n type, and the second semiconductor layer of the first AAT device and the second AAT device may be a 2D semiconductor in a p type.

According to an embodiment of the present disclosure, the second semiconductor layer of the first AAT device may be lightly doped with dopants, the dopants doped into the second semiconductor layer may be in the p-type, and an NDT peak of the first AAT device may be shifted right from an NDT peak of the second AAT device in a I-V graph.

According to an embodiment of the present disclosure, the first semiconductor layer of the first AAT device may be lightly doped with dopants, the dopants doped into the first semiconductor layer may be in the n type, and an NDT peak of the first AAT device may be shifted left from an NDT peak of the second AAT device in a I-V graph.

According to another aspect of the present disclosure, a quaternary inverter logic circuit may include a field effect transistor connected to a power supply terminal, and a 2D semiconductor device which is in-series connected to the field effect transistor.

According to an embodiment of the present disclosure, the field effect transistor may be one of a p-type field effect transistor or an n-type field effect transistor.

According to an embodiment of the present disclosure, a method for manufacturing a 2D transistor, may include forming a gate electrode, forming a gate insulating film on the gate electrode, forming a 2D semiconductor layer provided on the gate insulating film and provided in a hetero-junction structure having a staggered band gap, forming a source electrode and a drain electrode connected to the 2D semiconductor layer and spaced apart from each other, and lightly doping dopants into a portion of the 2D semiconductor layer. The two dimensional semiconductor layer may include a first semiconductor layer and a second semiconductor layer having mutually different electrical characteristics and at least partially overlapped with each other, and the dopants may be doped into one of the first semiconductor layer and the second semiconductor layer.

According to an embodiment of the present disclosure, the one of the first semiconductor layer and the second semiconductor layer may be a 2D semiconductor layer provided in an n type, and another of the first semiconductor layer and the second semiconductor layer may be a 2D semiconductor layer provided in a p type.

According to an embodiment of the present disclosure, a dopant doped into the 2D semiconductor provided in the p type, of the first semiconductor layer and the second semiconductor layer may be a p-type dopant.

According to an embodiment of the present disclosure, a dopant doped into the 2D semiconductor provided in the n type, of the first semiconductor layer and the second semiconductor layer may be a n-type dopant.

### BRIEF DESCRIPTION OF THE FIGURES

The above and other objects and features of the present disclosure will become apparent by describing in detail embodiments thereof with reference to the accompanying drawings.

FIG. 1 is a cross-sectional view illustrating a 2D semiconductor transistor, according to an embodiment of the present disclosure;

FIG. 2 is a graph illustrating curve I-V and the change in an NDT peak, in the state that a 2D semiconductor of the 2D semiconductor transistor illustrated in FIG. 1 is doped with dopants;

FIG. 3 is a graph illustrating curve I-V and the change in an NDT peak, in the state that a 2D semiconductor of the 2D semiconductor transistor illustrated in FIG. 1 is not doped with dopants;

FIG. 4 is a view illustrating the shift of the curve I-V of the 2D semiconductor transistor, as the 2D semiconductor illustrated in FIG. 1 is doped with dopants;

FIG. 5 is a view illustrating the shift of the NDT peak of the 2D semiconductor transistor, as the 2D semiconductor illustrated in FIG. 1 is doped with dopants;

FIG. 6 is a circuit diagram illustrating the 2D semiconductor, according to an embodiment of the present disclosure;

FIG. 7 is a graph illustrating an NDT peak in the 2D semiconductor illustrated in FIG. 6;

FIG. 8 is a view illustrating a quaternary inverter logic circuit including the 2D semiconductor, according to an embodiment of the present disclosure;

FIG. 9 is a view illustrating voltage transfer characteristics of the quaternary inverter logic circuit illustrated in FIG. 8;

FIG. 10 is a view illustrating the operating characteristic of the quaternary inverter logic circuit illustrated in FIG. 8;

FIG. 11 is a view illustrating a method for manufacturing a 2D semiconductor transistor, according to an embodiment of the present disclosure; and

FIGS. 12 to 15 are cross-sectional views illustrating a method for manufacturing a 2D semiconductor transistor, according to an embodiment of the present disclosure.

### DETAILED DESCRIPTION

Objects, advantages, and novel features of the present disclosure will be more apparent from the following description associated with accompanying drawings and an exemplary embodiment. In adding the reference numerals to the components of each drawing, it should be noted that the identical or equivalent component is designated by the identical numeral even when they are displayed on other drawings. In addition, in the following description of the present disclosure, a detailed description of well-known art or functions will be ruled out in order not to unnecessarily obscure the gist of the present disclosure.

In addition, the accompanying drawings are provided to allow those skilled in the art to easily understand an embodiment of the present disclosure, and the technical spirit of the present disclosure is not limited thereto accompanying drawings. The present disclosure is to cover all modifications, equivalents, and alternatives falling within the spirit and scope of the present disclosure.

In addition, although the terms including ordinal numbers, such as “first” and “second” may be used to describe various components, the components are not limited to the terms. The terms are used only to differentiate one component from another component.

Hereinafter, embodiments of the present disclosure will be described with reference to accompanying drawings.

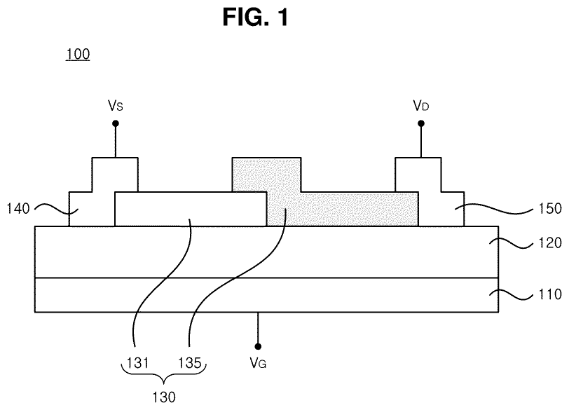

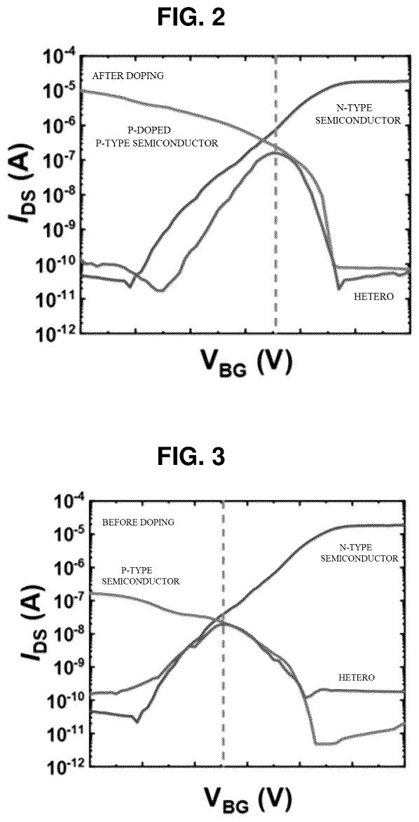

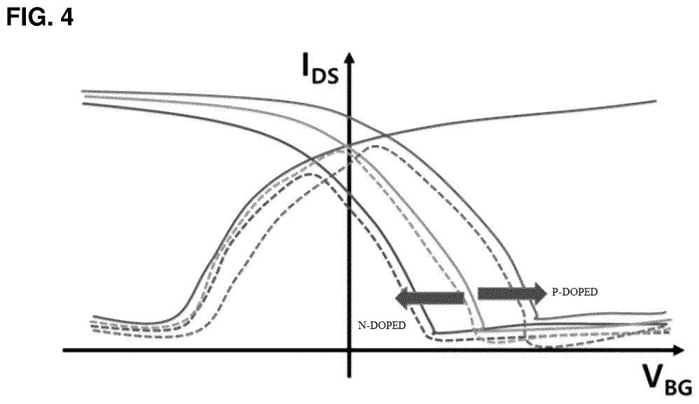

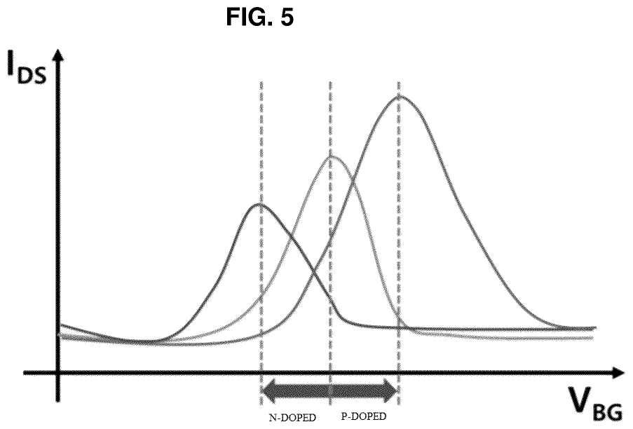

FIG. 1 is a cross-sectional view illustrating a 2D semiconductor transistor, according to an embodiment of the present disclosure, FIG. 2 is a graph illustrating curve I-V and the change in an NDT peak, in the state that a 2D semiconductor of the 2D semiconductor transistor illustrated in FIG. 1 is doped with dopants, FIG. 3 is a graph illustrating curve I-V and the change in an NDT peak, in the state that a 2D semiconductor of the 2D semiconductor transistor illustrated in FIG. 1 is not doped with dopants, FIG. 4 is a view illustrating the shift of the curve I-V of the 2D semiconductor transistor, as the 2D semiconductor illustrated in FIG. 1 is doped with dopants, and FIG. 5 is a view illustrating the shift of the NDT peak of the 2D semiconductor transistor, as the 2D semiconductor illustrated in FIG. 1 is doped with dopants.

Referring to FIGS. 1 to 5, according to an embodiment of the present disclosure, a 2D semiconductor transistor 100 may be an anti-ambipolar transistor (AAT) having the hetero-junction between a semiconductor channel in an n-type and a semiconductor channel in a p type.

The 2D semiconductor transistor 100 may include a gate electrode 110, a gate insulating film 120, a 2D semiconductor layer 130, a source electrode 140, and a drain electrode 150.

The gate electrode 110 may include a conductive material, and may be formed through various manners. For example, the gate electrode 110 may be a portion of a silicon substrate heavily doped with p-type dopants.

According to an embodiment of the present disclosure, the gate electrode 110 may include a conductive film including a material. For example, the gate electrode 110 may include at least one of gold (Au), silver (Ag), platinum (Pt), chromium (Cr), titanium (Ti), copper (Cu), aluminum (Al), tantalum (Ta), molybdenum (Mo), tungsten (W), nickel (Ni) palladium (Pd), or the alloy thereof.

In addition, the gate electrode 110 may include a metal oxide. For example, the gate electrode 110 may include at least one of an indium tin oxide (ITO), an indium zinc oxide (IZO), an indium tin oxide (ITZO), an Al-doped zinc oxide (AZO), or a gallium zinc oxide (GZO).

The gate insulating film 120 may be provided on the gate electrode 110.

The gate insulating film 120 may include an inorganic insulating material. For example, the gate insulating film 120 may include at least one of silicon nitride (SiN), silicon dioxide (SiO₂), germanium dioxide (GeO₂), titanium dioxide (TiO₂), zinc oxide (ZnO), indium tin oxide (ITO), AZO compound (AZO), magnesium oxide (MgO), aluminum oxide (Al₂O₃), zirconium dioxide (ZrO₂), zirconium silicate (ZrSiO₄), hafnium silicate (HfSiO₄), silicon nitride (Si₃N₄), strontium oxide (SrO), tantalum pentoxide (Ta₂O₅), yttrium oxide (Y₂O₃), hafnium oxide (HfO₂), lanthanum oxide (La₂O₃), barium oxide (BaO), lanthanum ruthenium oxide (LaLuO₂) or lanthanum alum (LaAlO₃).

Meanwhile, according to an embodiment of the present disclosure, the above description has been made in that that the gate insulating film 120 is an inorganic insulating film, but the present disclosure is not limited thereto. The shape or the material of the gate insulating film 120 may be varied if necessary. The gate insulating film 120 may include an organic insulating material. However, when the gate insulating film 120 includes an inorganic insulating material, the gate insulating film 120 may show excellent mechanical and chemical stability, as compared to an insulating film including the organic insulating material.

The 2D semiconductor layer 130 may operate as a 2D semiconductor channel of the 2D semiconductor transistor 100. The 2D semiconductor layer 130 may be provided on the gate insulating film 120. The 2D semiconductor layer 130 may include dichalcogen which is transition metal. The 2D semiconductor layer 130 may include at least one of MoS₂, WS₂, ReS₂, ReSe₂, PtSe2, HfS2, MoSe₂, HfSe₂, HfTe₅, HfTe₂, ZrS₂, ZrSe₂, ZrTe₂, ZrS₃, ZrS₅, ZrTe₃, WSe₂, MoSe₂, black phosphorus (BP), 2D tellurium, GeSe, GaSe, GeAs, black AsP, or a-MnS.

Meanwhile, according to an embodiment of the present disclosure, although the 2D semiconductor layer 130 has been described as a channel of the 2D semiconductor transistor 100, the present disclosure is not limited thereto. For example, the channel of the 2D semiconductor transistor includes a group III-V semiconductor material, instead of the 2D semiconductor layer 130. For example, the group III-V semiconductor material may include at least one of Ge, Si, SiGe, GaAs, GaN, GaP, InP, InAs, or InSb.

For example, the channel of the 2D semiconductor transistor 100 includes an organic semiconductor material. For example, the organic semiconductor material may include at least one of Pentacene, rubrene, Alq3, tetracene, DFH-4T, perylene, poly[9,9 dioctyl-fluorene-co-bithiophene] (F8T2), poly[2-methoxy-5-(3,7-dimethyloctyloxy)]-1,4-phenylenevinylene (MDMO-PPV), regioregular poly[3-hexylthiophene] (P3HT) polytriarylamine (PTAA), poly-[2,5-thienylene vinylene] (PVT), Naphthalene tetracarboxylic diimide (NDI), or perylene diimide (PDI).

The 2D semiconductor layer 130 may include a first semiconductor layer 131 and a second semiconductor layer 135. The first semiconductor layer 131 and the second semiconductor layer 135 may have the form in which the first semiconductor layer 131 and the second semiconductor layer 135 are at least partially overlapped with each other. For example, as at least a portion of the second semiconductor layer 135 is provided on the first semiconductor layer 131, the portion of the second semiconductor layer 135 may be overlapped with the portion of the first semiconductor layer 131.

The first semiconductor layer 131 and the second semiconductor layer 135 may have mutually different electrical characteristics. For example, one (for example, the first semiconductor layer 131) of the first semiconductor layer 131 and the second semiconductor layer 135 may be a 2D semiconductor provided in an n type. In addition, another one (for example, the second semiconductor layer 135) of the first semiconductor layer 131 and the second semiconductor layer 135 may be a 2D semiconductor provided in a p type. Therefore, in a region where the first semiconductor layer 131 and the second semiconductor layer 135 are overlapped with each other, the first semiconductor layer 131 and the second semiconductor layer 135 may be hetero-junctioned.

In addition, one (for example, the second semiconductor layer 135) of the first semiconductor layer 131 and the second semiconductor layer 135 may be lightly doped with dopants. In this case, since the second semiconductor layer 135 is a p-type 2D semiconductor layer, the dopant may be a p-type dopant.

Meanwhile, according to an embodiment of the present disclosure, p-type dopants are lightly doped into the p-type second semiconductor layer 135, but the present disclosure is not limited thereto. The first semiconductor layer 131 in the n-type may be lightly doped with dopants

As described above, the 2D semiconductor layer 130 may have a structure in which the first semiconductor layer 131 and the second semiconductor layer 135 having different electrical characteristics are hetero-junctioned. In addition, the 2D semiconductor layer 130 has a staggered band gap. In the second semiconductor layer 130 having the staggered band gap, one type of carrier (for example, an electron) may obtain energy when transferring between bands, and another type of carrier (for example, a hole) may require energy for transferring between the bands.

The 2D semiconductor layer 130 may provide a flat surface. In particular, since the 2D semiconductor layer 130 has no defect such as surface dangling bonding, a hetero-interface having no defect may be formed when the first semiconductor layer 131 and the second semiconductor layer 135 are hetero-junctioned. Accordingly, the 2D semiconductor layer 130 may prevent an excessive current.

The source electrode 140 and the drain electrode 150 may be disposed to be spaced apart from each other on the 2D semiconductor layer 130. In more detail, the source electrode 140 may be connected to one (for example, the first semiconductor layer 131) of the first semiconductor layer 131 and the second semiconductor layer 135. In addition, the drain electrode 150 may be connected to another one (for example, the second semiconductor layer 135) of the first semiconductor layer 131 and the second semiconductor layer 135.

The source electrode 140 and the drain electrode 150 may include a conductive material. For example, the source electrode 140 and the drain electrode 150 may include a metal material or a metal oxide.

When the source electrode 140 and the drain electrode 150 include a metallic material, the source electrode 140 and the drain electrode 150 may include at least one of gold (Au), silver (Ag), platinum (Pt), chromium (Cr), titanium (Ti), copper (Cu), aluminum (Al), tantalum (Ta), molybdenum (Mo), tungsten (W), nickel (Ni), palladium (Pd), or the alloy thereof.

When the source electrode 140 and the drain electrode 150 include a metal oxide, the source electrode 140 and the drain electrode 150 may include at least one of an indium tin oxide (ITO), an indium tin oxide (IZO), an indium tin oxide (ITZO), an Al-doped zinc oxide (AZO), and a gallium zinc oxide (GZO).

According to an embodiment of the present disclosure, the 2D semiconductor transistor 100 may further include a protective layer (not shown) covering the gate insulating film 120, the 2D semiconductor layer 130, the source electrode 140, and the drain electrode 150.

Since the 2D semiconductor transistor 100 according to an embodiment of the present disclosure as described above has a structure in which an n-type FET and a p-type FET are connected through hetero-junction between the first semiconductor layer 131 and the second semiconductor layer 135, a negative-differential transconductance (NDT) peak may be formed in a section in which the I-V curve of the n-type FET is overlapped with the I-V curve of the p-type FET IV curve.

In addition, according to an embodiment of the present disclosure, as the 2D semiconductor transistor 100 operates at a higher on/off current ratio, the 2D semiconductor transistor 100 may have a peak to valley current ratio (PVCR).

In addition, as illustrated in FIGS. 2 and 3, an AAT device, such as the 2D semiconductor transistor 100 according to one embodiment of the present disclosure, has an NDT peak and may operate as a binary inverter.

In addition, as illustrated in FIGS. 2 and 3, it may be recognized that the 2D semiconductor transistor 100 according to an embodiment of the present disclosure is shifted right in the I-V curve, as compared to a 2D semiconductor transistor in which neither first semiconductor layer 131 nor second semiconductor layer 135 is doped with dopants, because the 2D semiconductor transistor 100 according to an embodiment of the present disclosure in which one (for example, the second semiconductor layer 135) of the first semiconductor layer 131 and the second semiconductor layer 135 is lightly doped with the n-type dopants or the p-type dopants. In addition, it may be recognized that the NDT peak of the 2D semiconductor transistor 100 may be shifted righter, as the I-V curve is shifted righter.

As illustrated in FIG. 4, the 2D semiconductor transistor 100 according to an embodiment of the present disclosure may be shifted left in the I-V curve, as the first semiconductor layer 131 is lightly doped with the n-type dopants and the doping concentration is increased. Accordingly, as illustrated in FIG. 5, the negative-differential-transconductance (NDT) peak of the 2D semiconductor transistor 100 may be shifted left.

As illustrated in FIG. 4, the 2D semiconductor transistor 100 according to an embodiment of the present disclosure may be shifted right in the I-V curve, as the first semiconductor layer 135 is lightly doped with the p-type dopants and the doping concentration is increased. Accordingly, as illustrated in FIG. 5, the NDT peak of the 2D semiconductor transistor 100 may be shifted right.

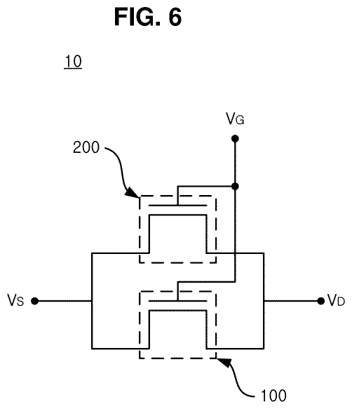

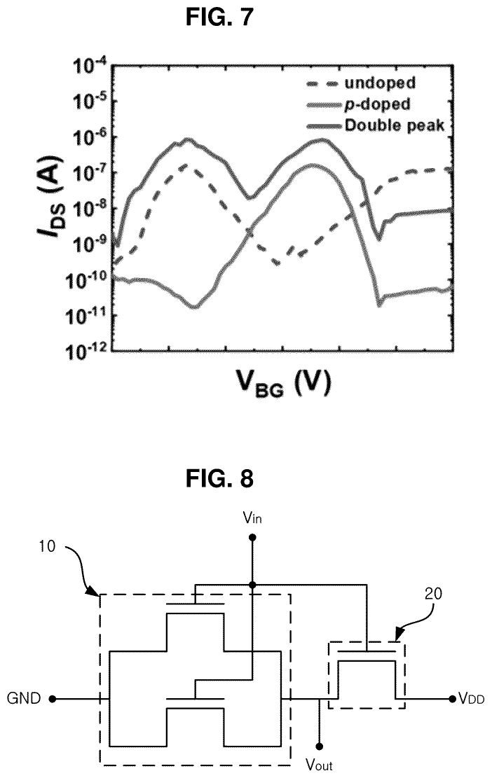

FIG. 6 is a circuit diagram illustrating the 2D semiconductor according to an embodiment of the present disclosure, and FIG. 7 is a view illustrating the NDT peak of the 2D semiconductor illustrated in FIG. 6.

Referring to FIGS. 6 and 7, according to an embodiment of the present disclosure, the 2D semiconductor 10 may include two AAT devices 100 and 200 having mutually different electrical characteristics. For example, the 2D semiconductor 10 may include a first AAT device 100 and a second AAT device 200.

In this case, one (for example, the first AA device 100) of the first AAT device 100 and the second AAT device 200 may be the 2D semiconductor transistor illustrated in FIG. 1. In other words, one of the first semiconductor layer 131 and the second semiconductor layer 135 may be the 2D semiconductor transistor lightly doped with dopants.

Another device (for example, the second AA device 200) of the first AAT device 200 and the second AAT device 200 may be a 2D semiconductor transistor including the first semiconductor layer 131 and the second semiconductor layer 135 in which neither first semiconductor layer 131 nor second semiconductor layer 135 is doped with dopants.

A source electrode of the first AAT device 100 and a source electrode of the second AAT device 200 are connected to source terminals, and a drain electrode of the first AAT device 100 and a drain electrode of the second AAT device 200 may be connected to drain terminals. A gate electrode of the first AAT device 100 and a gate electrode of the second AA device 200 may be connected gate terminals.

As illustrated in FIG. 7, the first AAT device 100 and the second AAT device 200 may have mutually different NDT peaks. Accordingly, according to an embodiment of the present disclosure, the 2D semiconductor device 10 may have two NDT peaks. In other words, according to an embodiment of the present disclosure, the 2D semiconductor may be applied to a logic circuit, for example, a quaternary inverter logic circuit).

Meanwhile, although an embodiment has been described in that the second semiconductor layer 135 of the first AAT device 100 is lightly doped with dopants, and neither first semiconductor layer 131 nor second semiconductor layer 135 of the second AAT device 200 is doped with dopants, the present disclosure is not limited thereto. For example, the second semiconductor layer 135 of the first AAT device 100 may be lightly doped with the p-type dopants, and the first semiconductor layer 131 of the second AAT device 200 may be lightly doped with the n-type dopants.

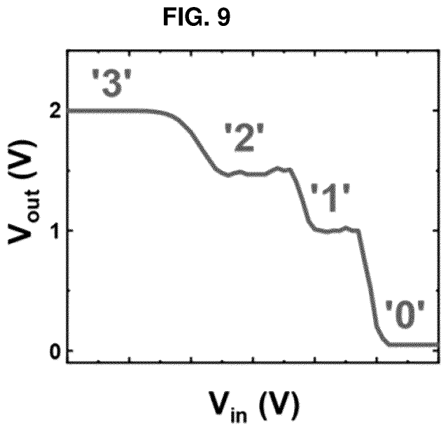

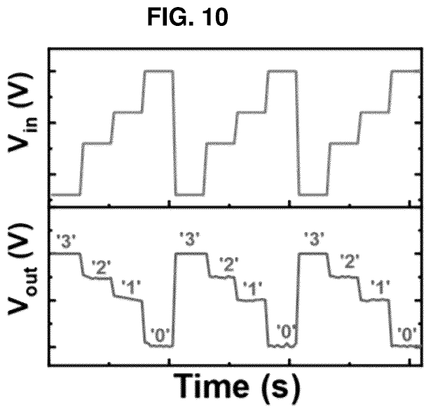

FIG. 8 is a view illustrating a quaternary inverter logic circuit including the 2D semiconductor, according to an embodiment of the present disclosure, FIG. 9 is a view illustrating voltage transfer characteristics of the quaternary inverter logic circuit including the 2D semiconductor illustrated in FIG. 8, and FIG. 10 is a view illustrating the operating characteristic of the quaternary inverter logic circuit illustrated in FIG. 8.

Referring to FIGS. 8 to 10, the quaternary inverter logic circuit may include a field effect semiconductor transistor 20 connected to a power terminal V_{DD} or an input terminal, and a two-dimensional semiconductor device 10 connected in series to the field effect transistor 20. In this case, the field effect transistor 20 may be a transistor including a p-type semiconductor channel, and the 2D semiconductor device 10 may be the 2D semiconductor device 10 illustrated in FIG. 7.

In other words, the 2D semiconductor 10 may include the AAT device 100 including a 2D semiconductor transistor having the first semiconductor layer 131 and the second semiconductor layer 135, one of which is lightly doped with dopants, and an AAT device 200 including a second semiconductor transistor having the first semiconductor layer 131 and the second semiconductor layer 135, in which neither first semiconductor layer 131 nor second semiconductor layer 135 are doped with dopants.

The source electrode of the field effect semiconductor transistor 20 may be electrically connected to the power terminal V_{DD}, the drain electrode of the field effect semiconductor transistor 20 may be electrically connected to the drain electrodes of the 2D semiconductor device 10, and the source electrodes of the 2D semiconductor device 10 may be electrically connected to the ground terminal GND.

The drain electrodes of the field effect semiconductor transistor 20 and the drain electrodes of the 2D semiconductor device 10 may be connected to the output terminal Vout, and the gate electrodes of the field effect semiconductor transistor 20 and the gate electrodes of the 2D semiconductor device 10 may be connected to the same input terminal Vin.

As described above, according to an embodiment of the present disclosure, the quaternary inverter logic circuit may include the field effect semiconductor transistor 20 provided in the p type, and the 2D semiconductor 10 having two NDT peaks.

Accordingly, as illustrated in FIG. 9, according to an embodiment of the present disclosure, the quaternary inverter logic circuit may operate as a quaternary inverter because the output voltage Vout is changed throughout four phases depending on the input voltage Vin.

In addition, as illustrated in FIG. 10, according to an embodiment of the present disclosure, the quaternary inverter logic circuit may stabilize an output voltage Vout resulting from a specific input Vin applied within a shorter period of time. In particular, it may be recognized that the output voltage Vout may be output to correspond to a time at which the specific input voltage Vin is applied.

Meanwhile, according to an embodiment of the present disclosure, the field effect transistor 20 has been described as the transistor including the p-type semiconductor channel, but the present disclosure is not limited thereto. For example, the field effect transistor 20 may be a transistor including a semiconductor channel provided in an n type.

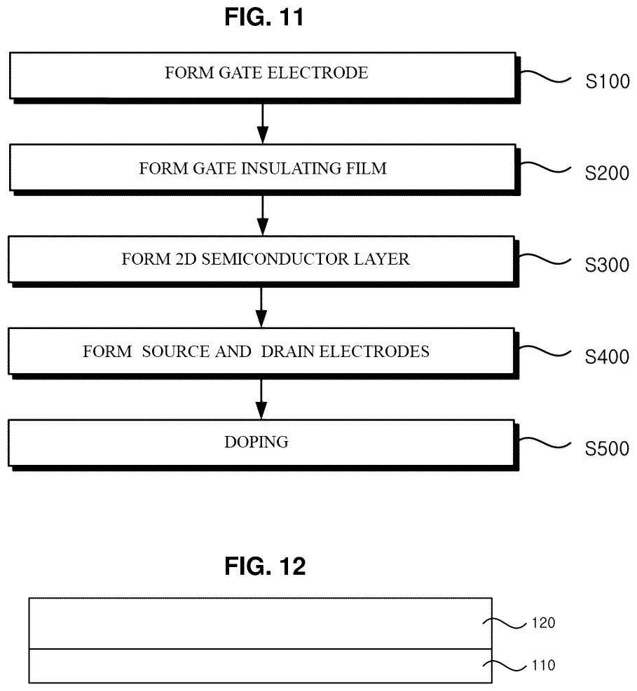

Hereinafter, a method for manufacturing the 2D semiconductor transistor will be described with reference to FIG. 11.

FIG. 11 is a view illustrating the method for manufacturing the 2D semiconductor transistor according to an embodiment of the present disclosure.

Referring to FIG. 11, according to an embodiment of the present disclosure, the method for manufacturing the 2D semiconductor transistor may include forming a gate electrode (S100), forming a gate insulating film (S200), forming a 2D semiconductor layer (S300), forming a source electrode and a drain electrode (S400), and doping a final structure (S500).

Hereinafter, the method for manufacturing the 2D semiconductor transistor illustrated in FIG. 11 will be described with reference to FIGS. 12 to 15.

FIGS. 12 to 15 are process cross-sectional views illustrating a method for manufacturing a 2D semiconductor transistor, according to an embodiment of the present disclosure.

First, referring to FIG. 12, the forming of the gate electrode (S100), may include forming the gate electrode by doping dopants into a silicon substrate. In this case, the dopants may be a p+ type-dopants.

Meanwhile, according to an embodiment of the present disclosure, although the above description has been made in that the gate electrode 110 is formed by doping dopants into the silicon substrate by way of example, the present disclosure is not limited thereto. For example, the gate electrode 110 may be formed by depositing a conductive material on the silicon substrate. In this case, the conductive material may include a metal material or a metal oxide. For example, the metal material may include at least one of gold (Au), silver (Ag), platinum (Pt), chromium (Cr), titanium (Ti), copper (Cu), aluminum (Al), tantalum (Ta), molybdenum (Mo), tungsten (W), nickel (Ni) palladium (Pd), or the alloy thereof. For example, the metal oxide may include at least one of an indium tin oxide (ITO), an indium zinc oxide (IZO), an indium tin oxide (ITZO), an Al-doped zinc oxide (AZO), or a gallium zinc oxide (GZO).

The forming of the gate insulating film (S200) may include forming the gate insulating film 120 by depositing an inorganic insulating material on the gate electrode 110. The gate insulating film 120 may include at least one of the inorganic insulating material or the organic material. The gate insulating film 120 may include an inorganic insulating material.

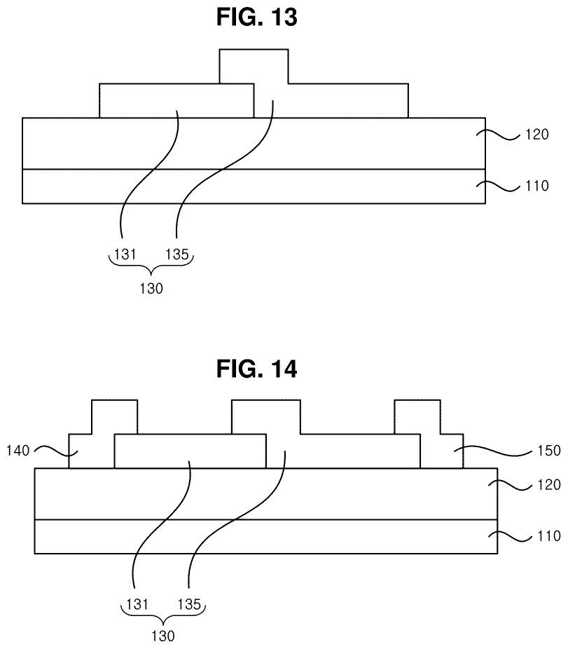

Referring to FIG. 13, the forming of the 2D semiconductor layer includes forming the 2D semiconductor layer 130 on the gate insulating film 120. In this case, the 2D semiconductor layer 130 may be formed by allowing the first semiconductor layer 131 and the second semiconductor layer 135 to be hetero-junctioned by sequentially forming the first semiconductor layer 131 and the second semiconductor layer 135.

In more detail, the first semiconductor layer 131 may be formed through a stamping process. For example, the first semiconductor layer 131 may be formed by picking up a 2D semiconductor piece, which is used to form the first semiconductor layer 131 on a carrier substrate (not illustrated), and stamping the first semiconductor layer 131 on the carrier substrate onto a self-growth single layer 130 In this case, the carrier substrate may have a structure in which a stamp (not illustrated) and an organic film (not illustrated) are stacked. In this case, the stamp may use a polydimethysiloxane (PDMS) stamp. In addition, the organic film, which serves as a propylene carbonate (PPC), is junctioned with the PDMS stamp to form the carrier substrate.

In other words, the first semiconductor layer 131 may be formed by picking up the 2D semiconductor piece using the stamp CS1 of the carrier substrate CS and stamping the semiconductor piece on a desired position of the self-growth single layer 130.

The second semiconductor layer 135 may be formed through the stamping process, which is similar to the first semiconductor layer 131. For example, the second semiconductor layer 135 may be formed by preparing for a 2D semiconductor piece, which is used to form the second semiconductor layer 135, on the organic film of the carrier substrate, disposing the second semiconductor layer 135 on the carrier substrate, on the gate insulating film, such that the second semiconductor layer 135 is at least partially overlapped with the first semiconductor layer 131, and removing the organic film.

Referring to FIG. 14, the forming of the source electrode and the drain electrode (S400) may include forming the source electrode 140 and the drain electrode 150 to be disposed to be spaced apart from each other on the second semiconductor layer 135.

To this end, a photoresist pattern (not illustrated) is formed on the self-growth single layer 130 having the second semiconductor layer 135, through a photolithography process. In this case, the photoresist pattern may expose a portion of the 2D semiconductor layer 130. For example, the photoresist pattern may expose a portion of the first semiconductor layer 131 and a portion of the second semiconductor layer 135.

After forming the photoresist pattern, a conductive film is entirely deposited and lift off to form the source electrode 140 connected to the first semiconductor layer 131 and the drain electrode 150 connected to the second semiconductor layer 135, thereby manufacturing the 2D semiconductor transistor 100.

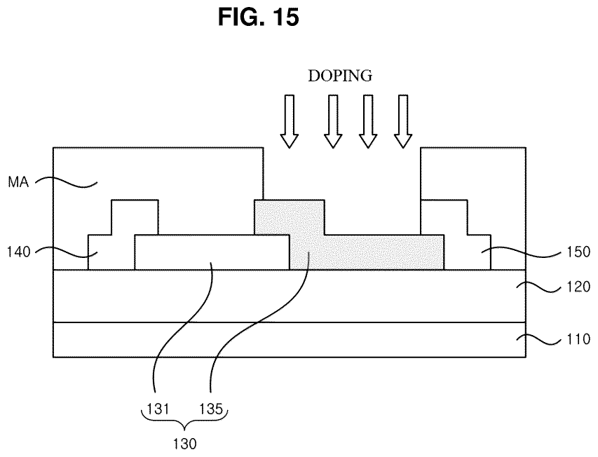

Referring to FIG. 15, the doping (S500) may include lightly doping dopants into one (for example, the second semiconductor layer 135) of the first semiconductor layer 131 and the second semiconductor layer 135.

In more detail, a mask MA is formed to expose at least a portion of the second semiconductor layer 135. In this case, the MA may be formed through the photolithography process.

Then, the dopants may be lightly doped into the second semiconductor layer 135. In this case, since the mask MA may expose only the second semiconductor layer 135, only the second semiconductor layer 135 may be lightly doped. In this case, since the second semiconductor layer 135 is a 2D semiconductor layer (or a p-type 2D semiconductor layer) provided in a p type, the dopant lightly doped may be a p-type dopant.

Meanwhile, according to an embodiment of the present disclosure, although the above description has been made in that p-type dopants are lightly doped into the p-type second semiconductor layer 135, but the present disclosure is not limited thereto. The first semiconductor layer 131 in the n-type may be lightly doped with n-type dopants. In this case, the mask MA may be provided in the form of exposing at least a portion of the first semiconductor layer 131.

As described above, according to an embodiment of the present disclosure, in the method for manufacturing the 2D semiconductor transistor 100, the second semiconductor layer 135 may be exposed and a doping process may be performed, thereby easily adjusting the electrical characteristic of the 2D semiconductor transistor 100 which serves as the AAT device.

Accordingly, the 2D semiconductors layers including two AAT devices having mutually different electrical characteristics may be simultaneously manufactured. In other words, the two AAT devices may be simultaneously manufactured such that the first semiconductor layer 131 and the second semiconductor layer 135 of one AAT device are lightly doped with dopants, and neither the first semiconductor layer 131 nor the second semiconductor layer 135 of another AAT device are doped with dopants.

The present disclosure is not limited to the above description, and it is obvious that the combination of at least two of embodiments or the combination of any one of the embodiments and a well-known technology may be included as a novel embodiment.

The detailed description of the present disclosure through a detailed embodiment has been described in detail, but the present disclosure is not limited thereto. It is obvious that modifications or variations are possible by those skilled in the art within the technical scope of the present disclosure.

The simple modification or variation of the present disclosure falls within the scope of the present disclosure. The detailed scope of the present disclosure will be apparent by attached claims.

While the present disclosure has been described with reference to embodiments thereof, it will be apparent to those of ordinary skill in the art that various changes and modifications may be made thereto without departing from the spirit and scope of the present disclosure as set forth in the following claims.

1. A two dimensional (2D) semiconductor transistor comprising:
a gate electrode;
a gate insulating film provided on the gate electrode;
a 2D semiconductor layer provided on the gate insulating film and provided in a hetero-junction structure having a staggered band gap;
a source electrode and a drain electrode provided on the two dimensional (2D) semiconductor layer and disposed to be spaced apart from each other,
wherein the 2D semiconductor layer includes a first semiconductor layer and a second semiconductor layer having mutually different electrical characteristics and at least partially overlapped with each other, and
wherein one of the first semiconductor layer and the second semiconductor layer is lightly doped with dopants.

2. The 2D semiconductor transistor of claim 1, wherein the one of the first semiconductor layer and the second semiconductor layer is a 2D semiconductor layer in an n type, and
wherein another of the first semiconductor layer and the second semiconductor layer is a 2D semiconductor provided layer in a p type.

3. The 2D semiconductor transistor of claim 2, wherein a dopant doped into the 2D semiconductor layer provided in the p type, of the first semiconductor layer and the second semiconductor layer is a p-type dopant.

4. The 2D semiconductor transistor of claim 2, wherein a dopant doped into the 2D semiconductor layer provided in the n-type, of the first semiconductor layer and the second semiconductor layer is an n-type dopant.

5. The 2D semiconductor transistor of claim 2, wherein the first semiconductor layer and the second semiconductor layer include dichalcogen which is transition metal.

6. The 2D semiconductor transistor of claim 5, wherein the first semiconductor layer and the second semiconductor layer includes:
at least one 2D semiconductor material of MoS₂, WS₂, ReS₂, ReSe₂, PtSe2, HfS₂, MoSe₂, HfSe₂, HfTe₅, HfTe₂, ZrS₂, ZrSe₂, ZrTe₂, ZrS₃, ZrS₅, ZrTe₃, WSe₂, MoSe₂, black phosphorus (BP), 2D tellurium, GeSe, GaSe, GeAs, black AsP, or a-MnS.

7. The 2D semiconductor transistor of claim 2, wherein the source electrode is connected to the one of the first semiconductor layer and the second semiconductor layer, and
wherein the drain electrode is connected to another of the first semiconductor layer and the second semiconductor layer.

8. The 2D semiconductor transistor of claim 1, wherein the gate insulating film includes:
at least one of SiN, SiO2, GeO₂, TiO₂, ZnO, ITO, AZO, MgO, Al₂O₃, ZrO₂, ZrSiO₄, HfSiO₄, Si₃N₄, SrO, Ta₂O₅, Y₂O₃, HfO₂, La₂O₃, BaO, LaLuO₂, or LaAlO₃.

9. A 2D semiconductor comprising:
a first AAT device and a second AAT device having mutually different electrical characteristics and connected to each other in parallel,
wherein the first AAT device and the second AAT device are 2D semiconductor transistors, respectively, each 2D semiconductor transistor having a 2D semiconductor layer provided in a hetero-junction structure having a staggered band gap,
wherein the 2D semiconductor layer includes:
a first semiconductor layer and a second semiconductor layer which have mutually different electrical characteristics and are at least partially overlapped with each other,
wherein one of the first semiconductor layer and the second semiconductor layer in one of the first AAT device and the second AAT device is lightly doped with a dopant, and
wherein another of the first AAT device and the second AAT device includes a first semiconductor layer and a second semiconductor layer which are not doped with dopants.

10. The 2D semiconductor of claim 9, wherein a negative-differential-transconductance (NDT) peak of the first AAT device and an NDT peak of the second AAT device are different from each other.

11. The 2D semiconductor of claim 10, wherein the first semiconductor layer of the first AAT device and the second AAT device is a 2D semiconductor in an n type, and
wherein the second semiconductor layer of the first AAT device and the second AAT device is a 2D semiconductor provided in a p type.

12. The 2D semiconductor of claim 11, wherein the second semiconductor layer of the first AAT device is lightly doped with dopants,
wherein the dopants doped into the second semiconductor layer are in the p-type, and
wherein an NDT peak of the first AAT device is shifted right from an NDT peak of the second AAT device in a I-V graph.

13. The 2D semiconductor of claim 11, wherein the first semiconductor layer of the first AAT device is lightly doped with dopants,
wherein the dopants doped into the first semiconductor layer are in the n type, and
wherein an NDT peak of the first AAT device is shifted left from an NDT peak of the second AAT device in a I-V graph.

14. A quaternary inverter logic circuit comprising:
a field effect transistor connected to a power supply terminal; and
the 2D semiconductor according to claim 9, which is in-series connected to the field effect transistor.

15. The quaternary inverter logic circuit of claim 14, wherein the field effect transistor is one of a p-type field effect transistor or an n-type field effect transistor.

16. A method for manufacturing a 2D transistor, the method comprising:
forming a gate electrode;
forming a gate insulating film on the gate electrode;
forming a 2D semiconductor layer provided on the gate insulating film and provided in a hetero-junction structure having a staggered band gap;
forming a source electrode and a drain electrode connected to the 2D semiconductor layer and spaced apart from each other; and
lightly doping dopants into a portion of the 2D semiconductor layer,
wherein the two dimensional semiconductor layer includes:
a first semiconductor layer and a second semiconductor layer having mutually different electrical characteristics and at least partially overlapped with each other, and
wherein the dopants are doped into one of the first semiconductor layer and the second semiconductor layer.

17. The method of claim 16, wherein the one of the first semiconductor layer and the second semiconductor layer is a 2D semiconductor layer provided in an n type, and
wherein another of the first semiconductor layer and the second semiconductor layer is a 2D semiconductor layer provided in a p type.

18. The method of claim 17, wherein a dopant doped into the 2D semiconductor provided in the p type, of the first semiconductor layer and the second semiconductor layer is a p-type dopant.

19. The method of claim 17, wherein a dopant doped into the 2D semiconductor provided in the n type, of the first semiconductor layer and the second semiconductor layer is a n-type dopant.
